(19) United States
(12) Patent Application Publication
(10) Pub. No.: US 2013/0133573 A1
(43) Pub. Date: May 30, 2013

(54) Mask for Deposition and Manufacturing Method of the Same

(71) Applicants: Sung-Joong JOO, Yongin-City (KR); Myung-Soo HUH, Yongin-City (KR); Suk-Won JUNG, Yongin-City (KR); Choel-Min JANG, Yongin-City (KR); Sung-Yong LEE, Yongin-City (KR); Cheol-Rae JO, Yongin-City (KR); In-Ae HAN, Yongin-City (KR)

(72) Inventors: Sung-Joong JOO, Yongin-City (KR); Myung-Soo HUH, Yongin-City (KR); Suk-Won JUNG, Yongin-City (KR); Choel-Min JANG, Yongin-City (KR); Sung-Yong LEE, Yongin-City (KR); Cheol-Rae JO, Yongin-City (KR); In-Ae HAN, Yongin-City (KR)

(73) Assignee: SAMSUNG MOBILE DISPLAY CO., LTD., Yongin-City (KR)

(21) Appl. No.: 13/467,387

(22) Filed: May 9, 2012

(30) Foreign Application Priority Data
Nov. 24, 2011 (KR) 10-2011-0123720

(51) Int. Cl. B05C 21/00; C23C 16/02; G03F 7/20; C23C 16/44

(52) U.S. Cl. 118/504; 427/248.1; 430/320

(57) ABSTRACT

A deposition mask includes a mask main body and a coating layer. The mask main body includes a plurality of slits penetrating the mask main body. The coating layer is coated on an entire surface of the mask main body. The coating layer is made of a material different from a material of the main body, and it has a magnetic force stronger than that of the main body. Each of the slits has an open area, and a thickness of the coating layer controls a width of the open area. A photolithography process is used to form the plurality of slits.

### CLAIM OF PRIORITY

This application makes reference to, incorporates the same herein, and claims all benefits accruing under 35 U.S.C. §119 from an application earlier filed in the Korean Intellectual Property Office on the 24 of Nov. 2011 and there duly assigned Serial No. 10-2011-0123720.

### BACKGROUND OF THE INVENTION

1. Field of the Invention

The present invention relates to a deposition mask and a method for manufacturing the deposition mask. More particularly, the present invention relates to a deposition mask for depositing an organic layer of an organic light emitting diode (OLED) display and a method for manufacturing the deposition mask.

2. Description of the Related Art

In general, an organic material deposition apparatus may deposit an organic material on a substrate in the form of a layer by applying current to the organic material in a vacuum state. The organic material deposition apparatus may include a deposition mask in order to form a desired pattern of an organic layer on the substrate. When the organic material is deposited on a large sized substrate, a fine metal mask (FMM) may be used as the deposition mask. Since the FMM is a high-definition metal mask having high durability and strength, the organic material can be deposited on the large sized substrate in a desired pattern.

The FMM may be a deposition mask for depositing an organic material on a large sized substrate in a high-definition pattern.

Using the FMM, a plurality of desired high-definition patterns of organic material can be formed on the substrate at once. Such an FMM may include a plurality of square shaped slits or a plurality of stripe shaped slits for allowing the organic material to pass through the FMM in order to deposit the organic material in a desired pattern.

The above information disclosed in this Background section is only for enhancement of an understanding of the background of the invention, and therefore it may contain information that does not form the prior art that is already known in this country to a person of ordinary skill in the art.

### SUMMARY OF THE INVENTION

The present invention has been developed in an effort to provide a deposition mask and a manufacturing method thereof having the advantage of manufacturing a deposition mask with slits, each having a finely controlled size.

An exemplary embodiment of the present invention provides a deposition mask which may include a mask main body and a coating layer. The mask main body may include a plurality of silts penetrating the mask main body. The coating layer may be coated on an entire surface of the mask main body by atomic layer deposition (ALD).

The coating layer may be made of material different from the material of the mask main body.

The mask main body may be a magnetic substance.

The coating layer may have a magnetic force stronger than that of the mask main body.

The coating layer may be made of oxide.

The slit may have an open area, and a thickness of the coating layer may control a width of the open area.

Another exemplary embodiment of the present invention provides a method for manufacturing a deposition mask. The method may include forming a plurality of slits at a mask main body to penetrate the mask main body, and forming a coating layer on an entire surface of the mask main body by atomic layer deposition (ALD).

The forming of a plurality of slits may be performed using a photolithography process.

In the forming of a coating layer, the thickness of the coating layer may be controlled so as to control a width of an open area of each slit.

The embodiments of the present invention provide a deposition mask including a slit having a finely controlled size and a method for manufacturing the mask.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 illustrates an organic material deposition apparatus including a deposition mask in accordance with a first exemplary embodiment of the present invention;

FIG. 2 is a perspective view that illustrates a deposition mask and a frame of FIG. 1.

FIG. 3 is a cross-sectional view of a deposition mask taken along the line of FIG. 2;

FIG. 4 is a flowchart that illustrates a method for manufacturing a deposition mask in accordance with a second exemplary embodiment of the present invention;

FIG. 5 is a cross-sectional view for describing a method for manufacturing a deposition mask according to the second exemplary embodiment of the present invention;

FIG. 6 is a cross-sectional view for describing a method for manufacturing a deposition mask in accordance with a third exemplary embodiment of the present invention;

FIG. 7 is a cross-sectional view for describing a method for manufacturing a deposition mask in accordance with a fourth exemplary embodiment of the present invention; and

FIG. 8 is a cross-sectional view that illustrates a deposition mask in accordance with a fifth exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art will realize, the described embodiments may be modified in various different ways, all without departing from the spirit or scope of the present invention.

Accordingly, the drawings and description are to be regarded as illustrative in nature and not restrictive. Like reference numerals designate like elements throughout the specification.

In the drawings, a size and a thickness of each element is approximately shown for better understanding and ease of description. Therefore, the present invention is not limited to the drawings.

In the drawings, the thickness of layers, films, panels, regions, etc. are exaggerated for clarity. In the drawings, a size and a thickness of each element are exaggerated for better understanding and ease of description. It will be understood that, when an element such as a layer, film, region, or substrate is referred to as being “on” another element, it can be directly on the other element or intervening elements may also be present.

In addition, unless explicitly described to the contrary, the word “comprise” and variations, such as “comprises” or “comprising”, will be understood to imply the inclusion of stated elements but not the exclusion of any other elements. It will be understood that when an element such as a layer, file, region, or substrate is referred to as being “on” another element, it can be on the other element or under the other element. The element may not be on another element in a gravitational direction.

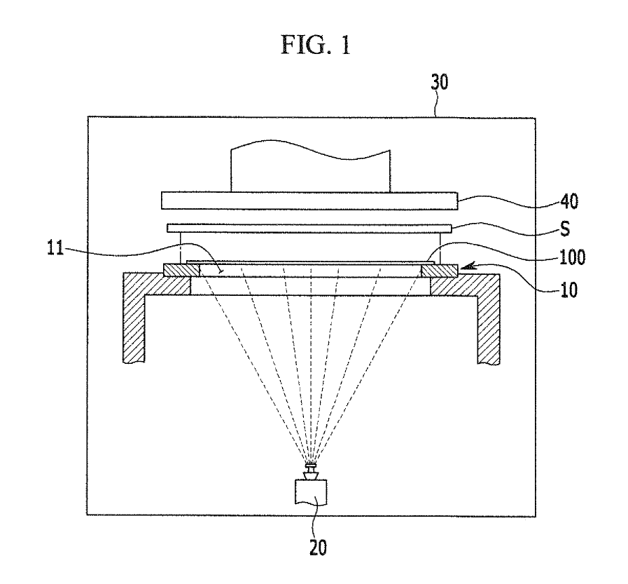

Hereinafter, a deposition mask in accordance with a first exemplary embodiment of the present invention will be described with reference to FIG. 1 to FIG. 3.

FIG. 1 illustrates an organic material deposition apparatus including a deposition mask in accordance with a first exemplary embodiment of the present invention.

As shown in FIG. 1, the organic material deposition apparatus may be used to form an organic layer of an organic light emitting diode (OLED) display. The organic material deposition apparatus may include a vacuum chamber 30, an organic material deposition crucible 20 installed in the vacuum chamber 30, a frame 10 disposed above the organic material deposition crucible 20, a deposition mask 100 supported by the frame 10, and a magnetic array 40 disposed above the deposition mask 100. The frame 10 may include an opening 11. An organic layer may be deposited on a substrate S using the organic material deposition apparatus as follows. The substrate S is disposed on the deposition mask 100. The magnetic array 40 may be disposed on the substrate S in order to closely stick the deposition mask 100 to the substrate S. Then, the organic material deposition crucible 20 is activated. As a result, organic material contained in the organic material deposition crucible 20 may be vaporized. The vaporized organic material may pass through the opening 11 of the frame 10 and slits of the deposition mask 100. Then, the vaporized organic material may be deposited on the substrate S as an organic layer having a predetermined pattern.

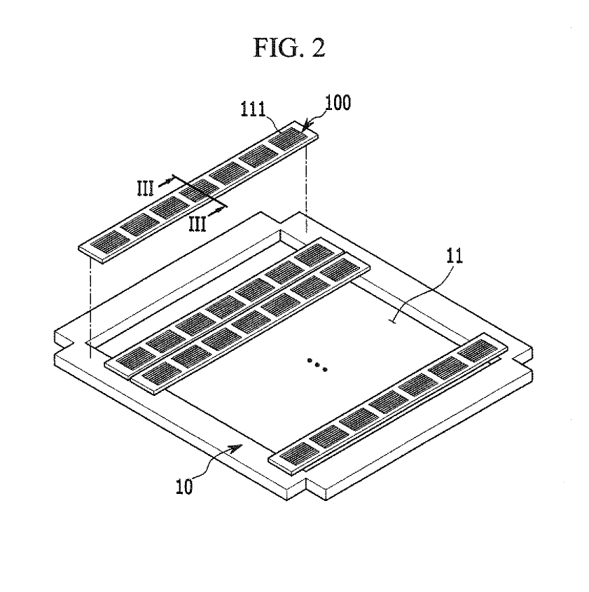

FIG. 2 is a perspective view that illustrates a deposition mask and a frame of FIG. 1.

As shown in FIG. 2, the deposition mask 100 may include a plurality of slits 111. Each one of a plurality of deposition masks 100 may be supported by the frame 10 having the opening 11. The deposition masks 100 may extend to the frame 10 and may be welded to the frame 10.

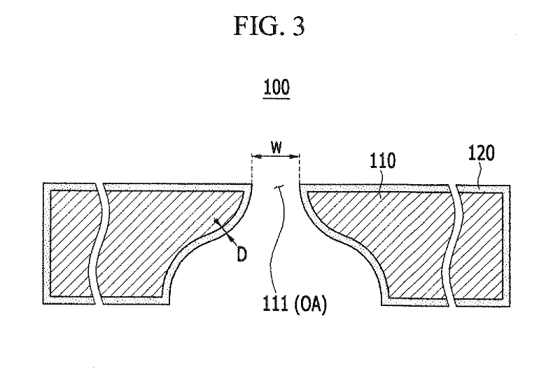

FIG. 3 is a cross-sectional view of a deposition mask taken along the line of FIG. 2.

As shown in FIG. 3, the deposition mask 100 may include a mask main body 110 and a coating layer 120.

The mask main body 110 may include a plurality of slits 111. The plurality of slits 111 may penetrate the mask main body 110. The organic material may pass through the slits 111 and may be deposited on the substrate S of FIG. 1 as an organic layer. The mask main body 110 may be made of metal having high durability and strength. The mask main body 110 may be a magnetic substance, but the present invention is not limited thereto. The mask main body 110 may include various types of metal, including nickel (Ni), invar, and aluminum (Al). The slit 111 may have an open area (OA).

The coating layer 120 may be coated on an entire surface of the mask main body 110. The deposition layer 120 may be formed through atomic layer deposition (ALD). Due to the characteristics of atomic layer deposition (ALD), the coating layer 120 may include various types of material. The coating layer 120 may be stably coated on the mask main body 110 regardless of the material of the mask main body 110. The coating layer 120 may be made of material different from the material of the mask main body 110. For example, the coating layer 120 may be made of iron (Fe) or ferrite. The coating layer 120 may have a magnetic force stronger than that of the mask main body 110. Since the coating layer 120 coated on the entire surface of the mask main body 110 has a stronger magnetic force than the mask main body 110, the deposition mask 100 may be closely stuck to the substrate S by the magnetic array 40 regardless of the material of the mask main body 110. The magnetic array 40 may be disposed on the substrate S in order to closely stick the deposition mask 100 on the substrate S.

The coating layer 120 may be formed by performing atomic layer deposition (ALD) multiple times. The thickness D of the coating layer 120 may be controlled by the number of times that atomic layer deposition is performed. By controlling the thickness D of the coating layer 120, the width of the open area (OA) of the slit 11 may be controlled. Accordingly, the size of the slit 111 of the deposition mask 100 may be finely controlled.

As described above, the width W of the open area OA of the slit 111 of the deposition mask 100 is controlled by controlling the thickness D of the coating layer 120. Since the thickness D of the coating layer 120 can be controlled by a thickness unit of an atomic layer, the width W of the open area OA of the silt 111 can be controlled by a nano-unit. Accordingly, an organic layer having a nano-unit pattern may be deposited on the substrate S in accordance with an embodiment of the present invention. As a result, a high resolution organic light emitting diode (OLED) display can be formed.

As described above, the deposition mask 100 according to the first exemplary embodiment of the present invention may include the main body 110 and the coating layer 120 coated on the entire surface of the mask main body 110. Accordingly, the deposition mask 100 according to the first exemplary embodiment of the present invention can be closely stuck to the substrate S of FIG. 1 by the magnetic array 40 of FIG. 1 regardless of the material of the mask main body 110 because the coating layer 120 may have a magnetic force stronger than that of the main body 110.

Furthermore, the coating layer 120 of the deposition mask 100 according to the first exemplary embodiment of the present invention may be coated by performing atomic layer deposition multiple times, and the thickness D of the coating layer 120 may be controlled by the number of times that atomic layer deposition is performed. Since the width W of the open area (OA) of the slit 111 may be controlled according to the thickness D of the coating layer 120, the width W of the open area OA of the slit 111 may be controlled by a nano-unit. Accordingly, a high resolution organic light emitting diode (OLED) display can be formed by depositing the organic layer having a nano-unit pattern on the substrate S.

In accordance with the first embodiment of the present invention, the coating layer 120 may be formed after the main body 110 extends to the frame 10 of FIG. 2 and is welded to the frame 10. Due to the extension and the welding, the slit 111 may be deformed. The width W of the open area OA of the slit 111 can be controlled by controlling the thickness D of the coating layer 120 even through the slit 111 becomes deformed.

Furthermore, the deposition mask 100 according to the first exemplary embodiment of the present invention may include the coating layer 120 made of a material different from that of the mask main body 110. For example, the coating layer 120 may be formed using material that can be etched by a predetermined etching solution, and the mask main body 110 may be formed using material that cannot be etched by the predetermined etching solution. In this case, the coating layer 120 can be removed from the mask main body 110 through dry etching using the predetermined etching solution after the organic material deposition process. Accordingly, the deposition mask 100 can be cleaned. After cleaning, the mask main body 110 can be reused. Accordingly, overall manufacturing cost and time can be reduced.

In addition, the deposition mask 100 according to the first exemplary embodiment of the present invention may include the coasting layer 120 made of a material different from that of the mask main body 110. The coating layer 120 may be formed using material having less chemical attraction to organic material passing through the slit 111. In this case, it can minimize the organic material absorbed by the deposition mask 100.

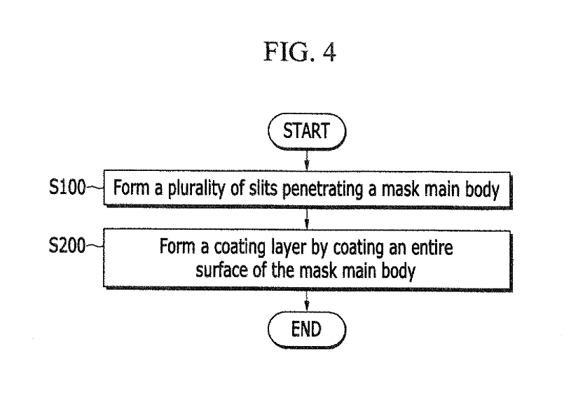

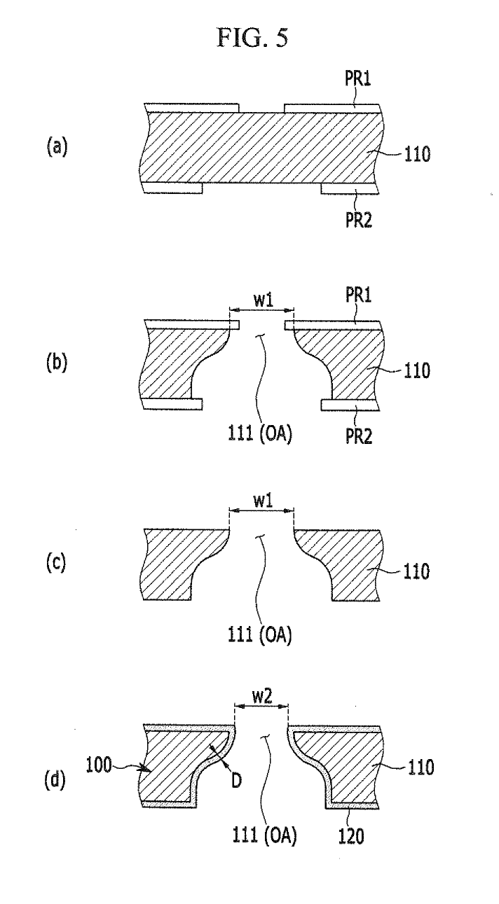

Hereinafter, a method for manufacturing a deposition mask in accordance with a second exemplary embodiment of the present invention will be described with reference to FIG. 4 and FIG. 5. The deposition mask according to the first exemplary embodiment of the present invention may be manufactured using the manufacturing method according to the second exemplary embodiment of the present invention.

FIG. 4 is a flowchart that illustrates a method for manufacturing a deposition mask in accordance with a second exemplary embodiment of the present invention, and FIG. 5 is a cross-sectional view for describing a method for manufacturing a deposition mask according to the second exemplary embodiment of the present invention.

Referring to FIG. 4 and FIG. 5, a plurality of slits 111 (FIG. 3) may be formed at a mask main body 110 at step S100. The slits 111 may be formed so as to penetrate the mask main body 110.

Particularly, a photolithography process may be performed to form the plurality of slits 111 at the mask main body 110.

Hereinafter, a process of forming the plurality of slits 111 at the mask main body 110 using the photolithography process will be described.

As shown in (a) of FIG. 5, a first photoresist layer PR1 may be formed on a top surface of the mask main body 110 and a second photoresist layer PR2 may be formed on a bottom surface of the mask main body 110. The first photoresist layer PR1 and the second photoresist layer PR2 may be sequentially exposed and developed using a photo mask. Accordingly, the first photoresist pattern PR1 may be formed on the top surface of the mask main body 110 and the second photoresist pattern PR2 may be formed on the bottom surface of the mask main body 110.

As shown in (b) of FIG. 5, a silt 111 having an open area OA with a first width W1 may be formed by etching the mask main body 110 through dry etching using the first photoresist pattern PR1 and the second photoresist pattern PR2 as a mask.

As shown in (c) of FIG. 5, the first photoresist pattern PR1 and the second photoresist pattern PR2 may be removed from the mask main body 110 using a lift off process or an ashing process.

Then, a coating layer 120 may be coated on the entire surface of the mask main body 110 using an atomic layer deposition method at step S200 of FIG. 4.

Particularly, as shown in (d) of FIG. 5, the coating layer 120 may be coated on the entire surface of the mask main body 110 using atomic layer deposition in order to control a thickness D of the coating layer 120. By controlling the thickness D of the coating layer 120, the first width W1 of the open area OA of the silt 111 of the mask main body 110 may be controlled so as to form a second width W2. As a result, the open area OA of the slit 111 of the deposition mask 100 may have the second width W2 by controlling the first width W1 of the open area OA by a nano-unit.

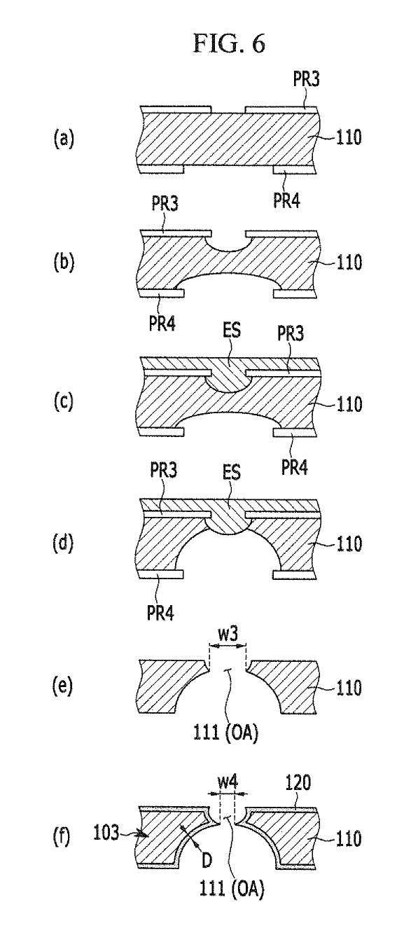

Hereinafter, a method for manufacturing a deposition mask in accordance with a third exemplary embodiment of the present invention will be described with reference to FIG. 6. The deposition mask according to the first exemplary embodiment of the present invention can be manufactured using the manufacturing method according to the third exemplary embodiment of the present invention.

FIG. 6 is a cross-sectional view for describing a method for manufacturing a deposition mask in accordance with a third exemplary embodiment of the present invention.

As shown in (a) of FIG. 6, a third photoresist layer PR3 may be formed on a top surface of the mask main body 110 and a fourth photoresist layer PR4 may be formed on a bottom surface of the mask main body 110. The third and fourth photoresist layers PR3 and PR4, respectively, may be sequentially exposed and developed using a photo mask. As a result, the third photoresist pattern PR3 may be formed on the top surface of the mask main body 110 and the fourth photoresist pattern PR4 may be formed on the bottom surface of the mask main body 110.

As shown in (b) of FIG. 6, a part of the mask main body 110 may be etched through dry etching using the third photoresist pattern PR3 and the fourth photoresist pattern PR4 as a mask.

As shown in (c) of FIG. 6, an etch stop layer ES may be formed so as to fill an upper part of the mask main body where the part of mask main body 110 is etched through dry etching.

As shown in (d) of FIG. 6, the bottom side of the mask main body 110 may be etched through dry etching using the fourth photoresist pattern PR4 as a mask. As shown in (e) of FIG. 6, the etch stop layer ES may be removed from the mask main body 110. The third and fourth photoresist patterns PR3 and PR4, respectively, may be removed from the mask main body 110 by performing a lift off process or an ashing process. As a result, the slit 111 having an open area OA with a third width W3 may be formed.

As shown in (f) of FIG. 6, a coating layer 120 may be coated on an entire surface of the mask main body 110 using atomic layer deposition in order to control a thickness D of the coating layer 120. By controlling the thickness D of the coating layer 120, the third width W3 of the open area OA of the slit 111 may be controlled so as to form a fourth width W4. As a result, the open area OA of the slit 111 of the deposition mask 103 may have the fourth width W4 by controlling the third width W3 of the open area OA by a nano-unit.

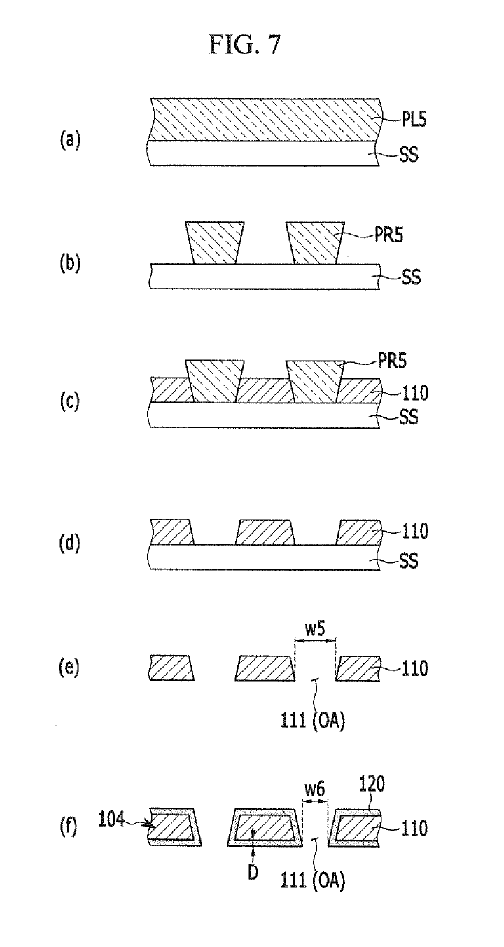

Hereinafter, a method for manufacturing a deposition mask in accordance with a fourth exemplary embodiment of the present invention will be described with reference to FIG. 7. The deposition mask according to the first exemplary embodiment of the present invention may be manufactured using the manufacturing method according to the fourth exemplary embodiment of the present invention.

FIG. 7 is a cross-sectional view for describing a method for manufacturing a deposition mask in accordance with a fourth exemplary embodiment of the present invention.

As shown in (a) of FIG. 7, a fifth photoresist layer PL5 may be formed on a top surface of a metal plate SS.

As shown in (b) of FIG. 7, the fifth photoresist layer PL5 may be exposed and developed using a photo mask. As a result, a fifth photoresist pattern PR5 may be formed on the top surface of the metal plate SS. The fifth photoresist pattern PR5 may have a taper shape.

As shown in (c) of FIG. 7, a mask main body 110 may be formed at the top surface of the metal plate SS using an electroplating process.

As shown in (d) of FIG. 7, the fifth photoresist pattern PR5 may be removed from the metal plate SS using a lift off process or an ashing process. As shown in (e) of FIG. 7, the metal plate SS may be removed from the mask main body 110 using dry etching. As a result, a slit 11 having an open area OA with a fifth width W5 may be formed.

As shown in (f) of FIG. 7, a coating layer 120 may be formed on the entire surface of the mask main body 110 by performing atomic layer deposition in order to control the thickness D of the coating layer 120. By controlling the thickness D of the coating layer 120, the fifth width W5 of the open area OA of the slit 111 of the mask main body 110 may be controlled so as to form the sixth width W6. Accordingly, the open area OA of the slit 111 of the deposition mask 104 may have the sixth width W6 by controlling the fifth width W5 by a nano-unit.

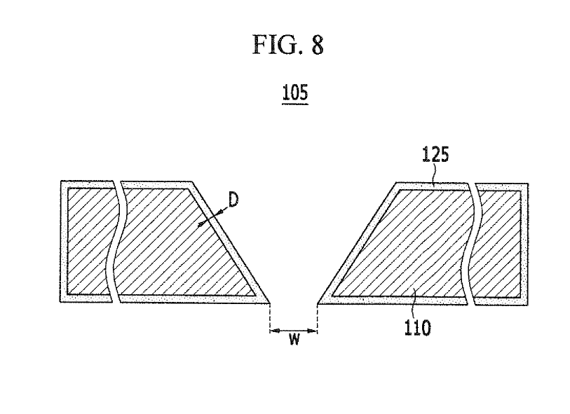

Hereinafter, a deposition mask according to a fifth exemplary embodiment of the present invention will be described with reference to FIG. 8.

As compared to the deposition mask according to the first embodiment, only distinguishing elements of the deposition mask according to the fifth embodiment will be described. Since the remaining elements of the deposition mask according to the fifth embodiment have a similar configuration, the detailed description thereof will be omitted herein. For better comprehension and ease of description, identical constituent elements between the first embodiment and the fifth embodiment will be described using the same reference numerals.

FIG. 8 is a cross-sectional view that illustrates a deposition mask in accordance with a fifth exemplary embodiment of the present invention.

As shown in FIG. 8, the deposition mask 105 according to the fifth exemplary embodiment of the present invention may include a mask main body 110 and a coating layer 125.

The coating layer 125 may be made of oxide, for example, alumina (Al₂O₃), nitrogen oxide (NOₓ), and silicon oxide (SiOₓ).

As described above, the deposition mask 105 according to the fifth exemplary embodiment of the present invention may include the coating layer 125 made of oxide. Accordingly, the coating layer 125 may prevent the mask main body 110 from being damaged by plasma or reactivity gas used in a sputter process or a chemical vapor deposition process even though the deposition mask 105 is used for the sputter process or the chemical vapor deposition process. Therefore, the coating layer 125 can minimize damage generated at the mask main body 110 during a deposition process.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition mask, comprising:
a mask main body including a plurality of silts penetrating the mask main body; and
a coating layer coated on an entire surface of the mask main body by atomic layer deposition (ALD).

2. The deposition mask of claim 1, wherein the coating layer is made of a material different from a material of the mask main body.

3. The deposition mask of claim 2, wherein the mask main body is a magnetic substance.

4. The deposition mask of claim 3, wherein the coating layer has a magnetic force stronger than a magnetic force of the mask main body.

5. The deposition mask of claim 3, wherein the coating layer is made of oxide.

6. The deposition mask of claim 1, wherein the mask main body is a magnetic substance.

7. The deposition mask of claim 1, wherein the coating layer has a magnetic force stronger than a magnetic force of the mask main body.

8. The deposition mask of claim 1, wherein the coating layer is made of oxide.

9. The deposition mask of claim 1, wherein each of the slits has an open area, and a thickness of the coating layer controls a width of the open area.

10. A method for manufacturing a deposition mask, the method comprising the steps of:
forming a plurality of slits at a mask main body so as to penetrate the mask main body; and
forming a coating layer on an entire surface of the mask main body by atomic layer deposition (ALD).

11. The method of claim 10, wherein the step of forming the plurality of slits is performed using a photolithography process.

12. The method of claim 10, wherein the step of forming the coating layer comprises controlling a thickness of the coating layer so as to control a width of an open area of each slit.

13. The method of claim 10, wherein the coating layer is made of a material different from a material of the mask main body.

14. The method of claim 13, wherein the mask main body is a magnetic substance.

15. The method of claim 14, wherein the coating layer has a magnetic force stronger than a magnetic force of the mask main body.

16. The method of claim 14, wherein the coating layer is made of oxide.

17. The method of claim 10, wherein the mask main body is a magnetic substance.

18. The method of claim 10, wherein the coating layer has a magnetic force stronger than a magnetic force of the mask main body.

19. The method of claim 10, wherein the coating layer is made of oxide.

20. The method of claim 10, wherein each of the slits has an open area, and a thickness of the coating layer controls a width of the open area.
